(19) United States
(12) Patent Application Publication
(10) Pub. No.: US 2005/0179340 A1
(43) Pub. Date: Aug. 18, 2005

(54) Surface acoustic wave device and surface acoustic wave filter comprising the device

(76) Inventors: Kouichi Yoshioka, Kyoto (JP); Morio Ogura, Osaka (JP); Masayuki Fujita, Kyoto (JP); Yasumi Kobayashi, Kyoto (JP); Kenichiro Wakisaka, Mie (JP)

Correspondence Address: MCDERMOTT WILL & EMERY LLP, 600 13TH STREET, N.W., WASHINGTON, DC, 20005-3096, US

(21) Appl. No.: 11/055,706

(22) Filed: Feb. 11, 2005

(30) Foreign Application Priority Data
Feb. 18, 2004 (JP) 2004-041175
Dec. 24, 2004 (JP) 2004-373304

(51) Int. Cl. H02N 2/00; H01L 41/04; H01L 41/08; H01L 41/18; H01L 21/4763

(52) U.S. Cl. 310/312; 310/311

(57) ABSTRACT

The present invention provides a surface acoustic wave device comprising an electrode 8 to serve as an interdigital transducer, the electrode 8 including a bottom Ti layer 2, Al alloy layer 3, upper Ti layer 4, and Al alloy layer 7 which are superposed one after another on a surface of a piezoelectric substrate 1. A thickness A of the bottom Ti layer 2 is greater than a thickness C of the upper Ti layer, and is not less than 50 nm nor more than 120 nm. The sum of the thickness A of the bottom Ti layer 2 and the thickness C of the upper Ti layer 4 is less than 150 nm. Accordingly, with the surface acoustic wave device, occurrence of migration is inhibited to obtain a higher durability than conventionally.

### REFERENCE TO RELATED APPLICATIONS

The priority applications Numbers 2004-041175 and 2004-373304 upon which this patent application is based is hereby incorporated by reference.

### BACKGROUND OF THE INVENTION

1. Field of the Invention

The present invention relates to surface acoustic wave devices comprising an electrode to serve as an interdigital transducer and formed on a piezoelectric substrate, and surface acoustic wave filters comprising the device.

2. Description of Related Art

Surface acoustic wave devices have heretofore been used in communications devices such as portable telephones as circuit elements of resonator filters, duplexers, etc. For example, FIG. 15 shows a surface acoustic wave device 5 comprising two interdigital transducers 52 each including a pair of interdigital electrodes 52a, 52a made of aluminum and each formed on a surface of a piezoelectric substrate 51, and reflectors 53, 53 including electrodes in the form of lattice arranged on opposite sides of the interdigital transducers 52, 52. Each of the interdigital transducers 52, 52 has connected thereto a pair of input pads 54, 54 and a pair of output pads 55, 55.

Communication devices have adapted for use at higher frequencies in recent years, which has made the frequencies and outputs of surface acoustic wave devices higher. The increases in operating frequencies entail the narrower width of the electrodes 52a. For example, when operating frequencies are in GHz band, the electrode 52a is less than 1 μm in line width. Applying voltage to the surface acoustic wave device having electrodes of such a narrow line width exerts a repeating stress by the surface acoustic wave generated on the surface of the piezoelectric substrate 51. When this stress exceeds a critical stress inherent in the material of the electrode 52a, stress migration occurs. Furthermore the increases in density of electronic current flowing through the electrode 52a produce electro migration. Consequently voids and hillocks are formed in the electrode 52a to deteriorate the electrode 52a due to the degradation of durability, resulting in the increase of short circuit and insertion loss.

With reference to FIG. 16, a surface acoustic wave device is proposed wherein an electrode 9 having a two-layer structure of a Ti layer 6 and an Al alloy layer 7 is formed on a piezoelectric substrate 1 (JP-A No. 368568/2002). The formation of the Ti layer 6 reduces the stress exerted on the electrode 9, to cause the surface acoustic wave device to exhibit more improved durability than that having an electrode of an aluminum single layer.

When the Ti layer 6 of the surface acoustic wave device shown in FIG. 16 is excessively thin in thickness, the repeating stress exerted by the piezoelectric substrate 1 generates remarkable stress migration, resulting in deterioration of the electrode 9. Therefore the Ti layer 6 need be formed so as to have a thickness of 50 nm or more.

When the Ti layer 6 is formed so as to have a thickness of greater than 50 nm to inhibit the stress migration, the occurrence of electro migration, however, encourages the formation of hillock H on a side surface of the Al alloy layer 7 particularly in the vicinity of a joint surface to the Ti layer 6, as seen in FIG. 17, to provide a short circuit between a pair of the adjacent electrodes. This gives rise to the problem of still failing to obtain a satisfactory durability. Furthermore, when the Ti layer 6 has a thickness of greater than 100 nm, a residue, in etching, is left partially on the side face of the Ti layer 6 and the piezoelectric substrate exposed by etching, to decrease working accuracy. This involves variations in device characteristics, entailing the problem of degraded insertion loss, an impaired yield, and a diminished durability.

Even the conventional surface acoustic wave device comprising the electrode of two-layer structure including the Ti layer and the Al alloy layer fails to overcome the problem of the diminished durability due to the stress migration and the electro migration.

### SUMMARY OF THE INVENTION

An object of the present invention is to provide a surface acoustic wave device which is adapted to inhibit effectively stress migration and electro migration to exhibit a higher durability than conventionally, and a surface acoustic wave filter including the device.

The present invention provides a surface acoustic wave device comprising an electrode to serve as an interdigital transducer and formed on a piezoelectric substrate, the electrode including a first layer made of Ti, a second layer made of Al or Al alloy, a third layer made of Ti, and a fourth layer made of Al or Al alloy, which are superposed one after another on a surface of the piezoelectric substrate. The thickness A of the first layer is greater than the thickness C of the third layer, and is not less than 50 nm nor more than 120 nm. The sum of the thickness A of the first layer and the thickness C of the third layer is less than 150 nm.

With the surface acoustic wave device of the present invention, the first layer made of Ti, the second layer made of Al or Al alloy, and the third layer made of Ti are formed in place of the conventional Ti layer providing a two-layer structure electrode, and an intermediate layer (the second layer) made of Al or Al alloy is interposed in the conventional Ti layer.

The present inventors experimentally find that the layer-structure, wherein the intermediate layer (the second layer) made of Al or Al alloy is interposed in the Ti layer efficient in the inhibition of stress migration, suppresses the growth of hillocks remarkably present in the vicinity of a joint surface to the Ti layer, i.e., suppresses electro migration, to improve a durability, and further to prevent degraded insertion loss and an impaired yield, whereby the inventors accomplish the present invention.

With the surface acoustic wave device of the present invention, the thickness A of the first layer made of Ti is greater than the thickness C of the third layer, and is not less than 50 nm nor more than 120 nm to thereby exhibit an improved durability. Furthermore, the sum (A+C) of the thicknesses of the first layer and the third layer which are made of Ti is less than 150 nm, to thereby diminish the insertion loss in the filter pass band.

Stated specifically, the thickness B of the second layer is not less than 10 nm nor more than 30 nm. The thickness B of not less than 10 nm renders the second layer uniform as a film. The thickness B of not more than 30 nm extends the range of the condition (the thickness of each layer) suitable for the improvement of the durability. If the thickness of the second layer is more than 30 nm, the second layer has hillocks remarkably grown thereof due to electro migration, to thereby reduce the durability.

Stated further specifically, the thickness A of the first layer is not more than 100 nm. This improves processing accuracy of the first layer by etching to improve production yield.

As described above, according to the present invention, the stress migration and the electro migration are effectively inhibited to thereby obtain the higher durability than conventionally.

### BRIEF DESCRIPTION OF THE DRAWINGS

FIG. 1 is a fragmentary sectional view showing a surface acoustic wave device according to the present invention;

FIG. 2 is a graph showing the evaluation results of durability when an Al alloy layer is 5 nm in thickness;

FIG. 3 is a graph showing the evaluation results of durability when the Al alloy layer is 10 nm in thickness;

FIG. 4 is a graph showing the evaluation results of durability when the Al alloy layer is 20 nm in thickness;

FIG. 5 is a graph showing the evaluation results of durability when the Al alloy layer is 30 nm in thickness;

FIG. 6 is a graph showing the evaluation results of durability when the Al alloy layer is 40 nm in thickness;

FIG. 7 is a graph showing the evaluation results of insertion loss when the Al alloy layer is 5 nm in thickness;

FIG. 8 is a graph showing the evaluation results of insertion loss when the Al alloy layer is 10 nm in thickness;

FIG. 9 is a graph showing the evaluation results of insertion loss when the Al alloy layer is 20 nm in thickness;

FIG. 10 is a graph showing the evaluation results of insertion loss when the Al alloy layer is 30 nm in thickness;

FIG. 11 is a graph showing the evaluation results of insertion loss when the Al alloy layer is 40 nm in thickness;

FIG. 12 is a diagram showing the basic construction of a surface acoustic wave filter of a ladder-type provided on a transmitting circuit;

FIG. 13 is a diagram showing the basic construction of a surface acoustic wave filter of a ladder-type provided on a receiving circuit;

FIG. 14 is a graph showing the frequency characteristics of insertion loss;

FIG. 15 is a plan view showing an electrode pattern of the surface acoustic wave device;

FIG. 16 is a fragmentary sectional view showing the conventional surface acoustic wave device;

FIG. 17 is a sectional view describing the problems of the conventional surface acoustic wave device.

### DETAILED DESCRIPTION OF THE INVENTION

With reference to the drawings, the embodiments of the present invention will be described below.

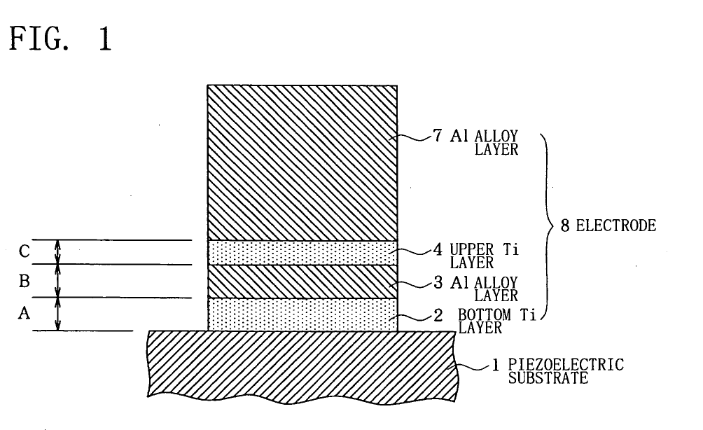

A surface acoustic wave device of the present invention comprises an electrode 8 to serve as an interdigital transducer and which is formed on a piezoelectric substrate 1, as shown in FIG. 1. The electrode 8 comprises, as superposed in the order starting from the piezoelectric substrate 1, a bottom Ti layer 2, Al alloy layer 3 made of AlVCu, upper Ti layer 4, and an Al alloy layer 7 made of AlVCu.

Fabricated for experiments were the surface acoustic wave devices each comprising an electrode 8 having the bottom Ti layer 2, the Al alloy layer 3 and the upper Ti layer 4 which were varied in thickness. These surface acoustic wave devices were checked for estimation of life according to diminished durability, and insertion loss within the filter pass band. The surface acoustic wave devices having the bottom Ti layer 2, the Al alloy layer 3 and the upper Ti layer 4 which were varied in thickness were checked as to whether short circuit occurs between the electrodes and between the electrode and the pad with use of a scanning electron microscope (SEM). Based on the results of the estimation of life, insertion loss measurement, and the occurrence of short circuit, if any, the bottom Ti layer 2, the Al alloy layer 3 and the upper Ti layer 4 were optimized in thickness.

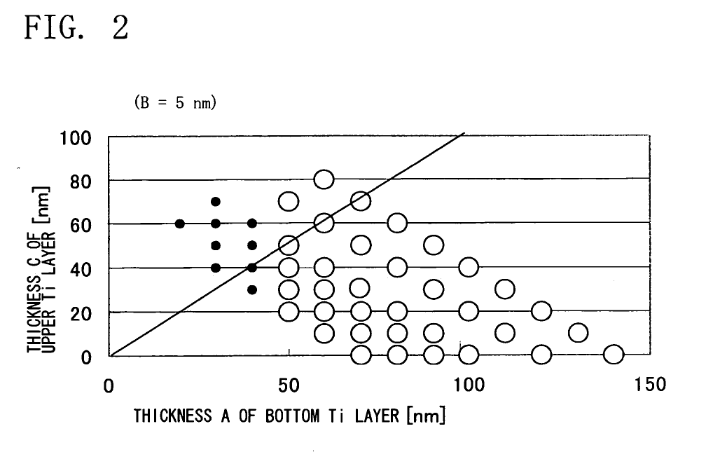

Plotted in FIGS. 2 to 6 are the evaluation results of the estimated life wherein the thickness A of the bottom Ti layer 2 is used to enter the horizontal axis and the thickness C of the upper Ti layer 4 is used to enter the vertical axis, when the thickness B of the Al alloy layer 3 is variously altered. Large black solid circles seen in the graph indicate the surface acoustic wave devices exhibiting the estimated life not less than 110% of that of surface acoustic wave devices having the conventional two-layer structure of the Ti layer and Al alloy layer (hereinafter referred to as the conventional surface acoustic wave device). White solid circles indicate the surface acoustic wave devices exhibiting the estimated life not less than 100% to less than 110% of that of the conventional surface acoustic wave device. Small solid black circles indicate the surface acoustic wave devices exhibiting the estimated life less than 100% of that of the conventional surface acoustic wave device.

Incidentally the estimation of life was performed in the following manner. Electric power of a constant frequency was applied to the devices as altered variously in the range of 2 to 3 W with the ambient temperature held at 50° C., to measure degradation time at each value of the applied power. In this case the degradation time was the time elapsed until loss caused by the application of power became 0.5 dB less than insertion loss before the application of power. The magnitude of the applied power was used to enter the horizontal axis in real number while the degradation time was used to enter the vertical axis in logarithm. The degradation time of the devices at each value of the applied power was plotted. With reference to the line obtained by connecting these plots, the degradation time in the case of the applied power of 1.2 W was estimated. The estimated degradation time was thus the estimated life.

Plotted in FIG. 2 are the evaluation results of the estimated life when the Al alloy layer 3 has a thickness B of 5 nm. As illustrated, when the bottom Ti layer 2 has a thickness A of 50 nm or more, the surface acoustic wave devices exhibit the estimated life not less than 100% to less than 110% of that of the conventional surface acoustic wave device, but fails to exhibit the estimated life greater than 110%.

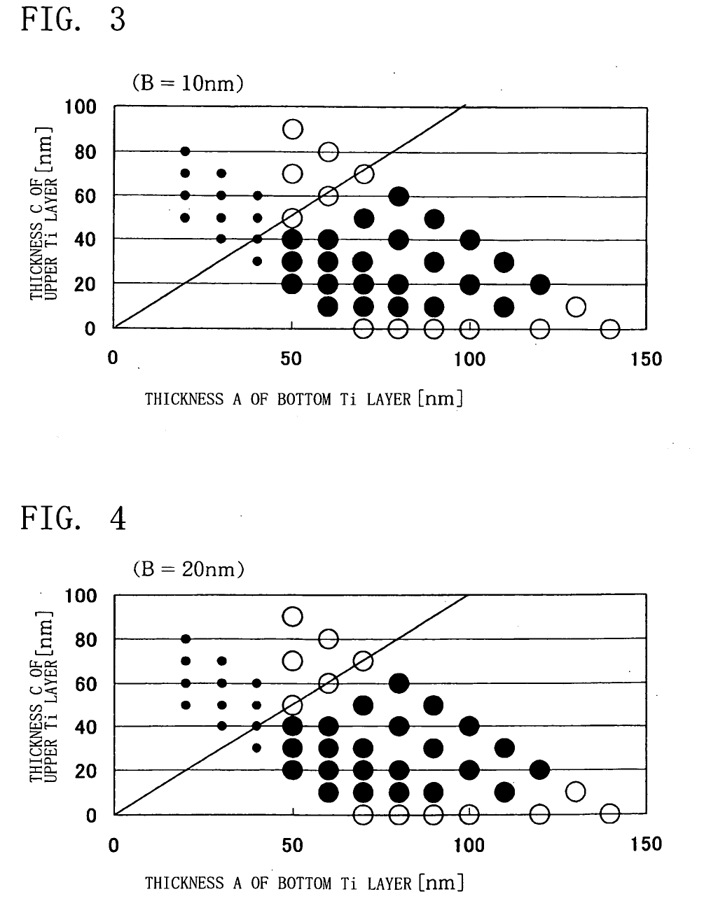

Plotted in FIG. 3 are the evaluation results of the estimated life when the Al alloy layer 3 has a thickness B of 10 nm. As illustrated, when the bottom Ti layer 2 has a thickness A greater than a thickness C of the upper Ti layer 4 and not less than 50 nm nor more than 120 nm, the surface acoustic wave devices exhibit the estimated life not less than 110% of that of the conventional surface acoustic wave device.

Plotted in FIG. 4 are the evaluation results of the estimated life when the Al alloy layer 3 has a thickness B of 20 nm. As illustrated, when the bottom Ti layer 2 has a thickness A greater than a thickness C of the upper Ti layer 4 and not less than 50 nm nor more than 120 nm, the surface acoustic wave devices exhibit the estimated life not less than 110% of that of the conventional surface acoustic wave device.

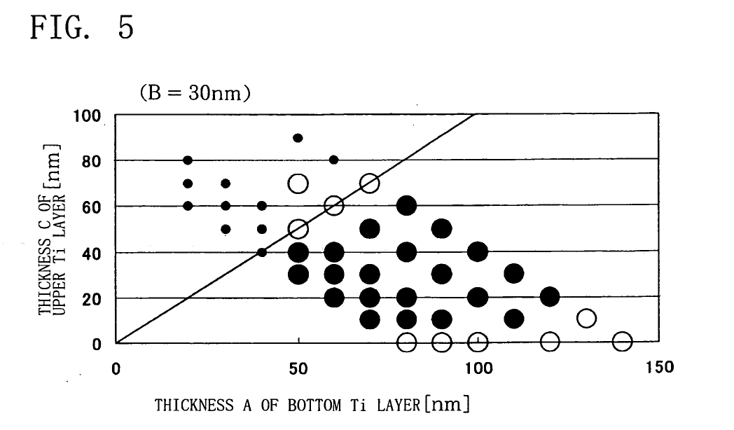

Plotted in FIG. 5 are the evaluation results of the estimated life when the Al alloy layer 3 has a thickness B of 30 nm. As illustrated, when the bottom Ti layer 2 has a thickness A greater than a thickness C of the upper Ti layer 4 and not less than 50 nm nor more than 120 nm, the surface acoustic wave devices exhibit the estimated life not less than 110% of that of the conventional surface acoustic wave device.

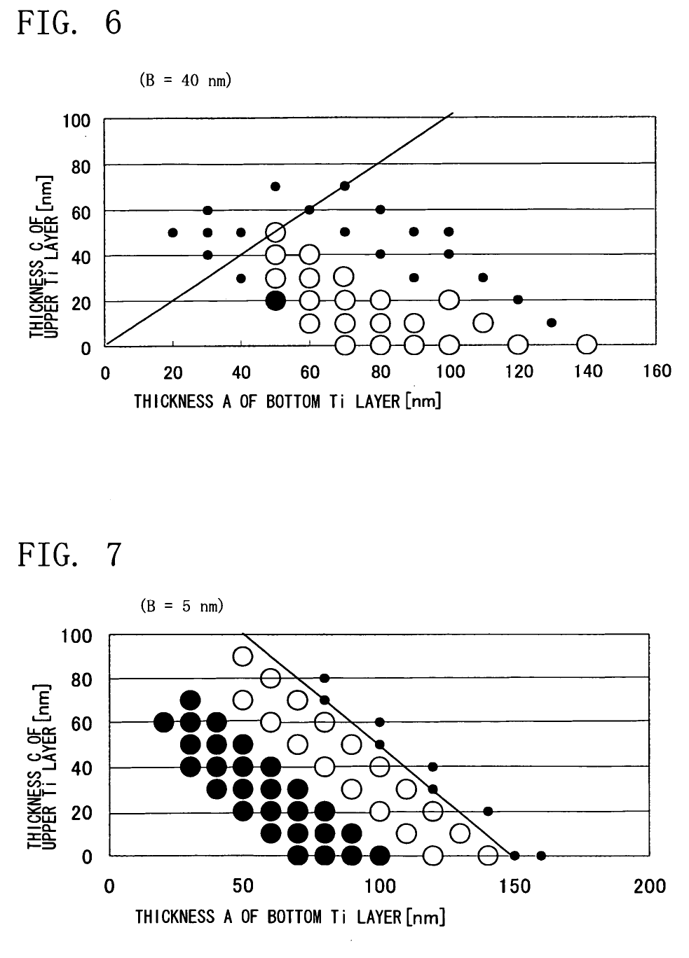

Plotted in FIG. 6 are the evaluation results of the estimated life when the Al alloy layer 3 has a thickness B of 40 nm. As illustrated, when the bottom Ti layer 2 has a thickness A of 50 nm and the upper Ti layer 4 has a thickness C of 20 nm, the surface acoustic wave devices exhibit the estimated life not less than 110% of that of the conventional surface acoustic wave device.

As described above, when the bottom Ti layer 2 has a thickness A greater than a thickness C of the upper Ti layer 4 and not less than 50 nm nor more than 120 nm, the devices exhibit the estimated life not less than 110% of that of the conventional surface acoustic wave devices, despite the thickness of the Al Alloy layer 3 insofar as the thickness B of the Al alloy layer 3 is in the range of 10 to 40 nm. Thus the thickness A of the bottom Ti layer 2 and the thickness C of the upper Ti layer 4 preferably have the following relationship:
A>C (Expression 1)
and 120 nm≧A≧50 nm

When the thickness A of the bottom Ti layer 2 is less than 50 nm, the effect is not available. This is because the excessively small thickness of the bottom Ti layer 2 causes a remarkable stress migration. Furthermore, when the thickness A of the bottom Ti layer 2 exceeds 120 nm, the effect is not available. This is because the excessively great thickness of the bottom Ti layer 2 reduces the effect of placement of the Al alloy layer 3 between the bottom Ti layer 2 and the upper Ti layer 4.

The thickness B of the Al alloy layer 3 has preferably the following relationship:
30 nm≧B≧10 nm (Expression 2)

When the thickness B of the Al alloy layer 3 is less than 10 nm, a problem of uniformity as a film will arise. When the thickness B is not less than 40 nm, the condition range in which the effect is available is made narrow, as seen in FIG. 6.

Plotted in FIGS. 7 to 11 are the evaluation results of the insertion loss within the filter pass band, wherein the thickness A of the bottom Ti layer 2 is used to enter the horizontal axis and the thickness C of the upper Ti layer 4 is used to enter the vertical axis, when the thickness B of the Al alloy layer 3 is variously altered. Large black solid circles seen in the graph indicate the surface acoustic wave devices wherein the maximum value (top loss) of insertion loss has a difference less than 0.05 dB with the maximum value of the conventional surface acoustic wave devices having the electrode of a single layer structure of an Al alloy layer (hereinafter referred to as the conventional surface acoustic wave device). White solid circles indicate the surface acoustic wave devices wherein the maximum value of insertion loss has a difference not less than 0.05 dB to less than 0.1 dB with the maximum value of the conventional surface acoustic wave devices. Small solid black circles indicate the surface acoustic wave devices wherein the maximum value of insertion loss has a difference greater than 0.1 dB with the maximum value of the conventional surface acoustic wave devices.

Plotted in FIG. 7 are the evaluation results of the insertion loss when the Al alloy layer 3 has a thickness B of 5 nm. As illustrated, when the sum (A+C) of the thickness A of the bottom Ti layer 2 and the thickness C of the upper Ti layer 4 is less than 150 nm, the maximum value of insertion loss has a difference less than 0.1 dB with the maximum value of the conventional surface acoustic wave devices.

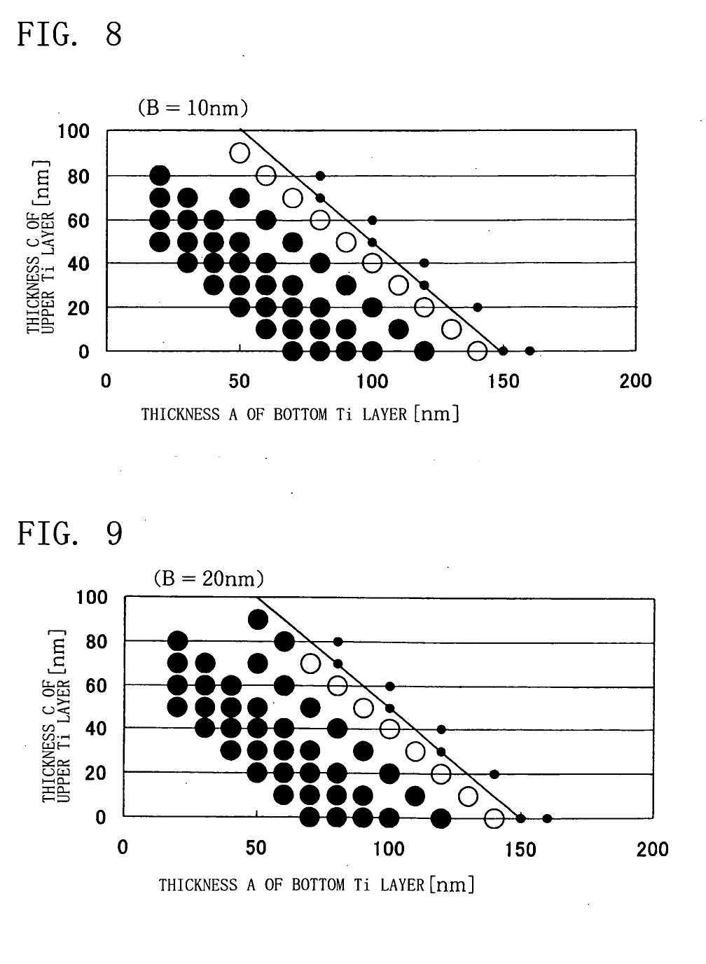

Plotted in FIG. 8 are the evaluation results of the insertion loss when the Al alloy layer 3 has a thickness B of 10 nm. As illustrated, when the sum (A+C) of the thickness A of the bottom Ti layer 2 and the thickness C of the upper Ti layer 4 is less than 150 nm, the maximum value of insertion loss has a difference less than 0.1 dB with the maximum value of the conventional surface acoustic wave devices.

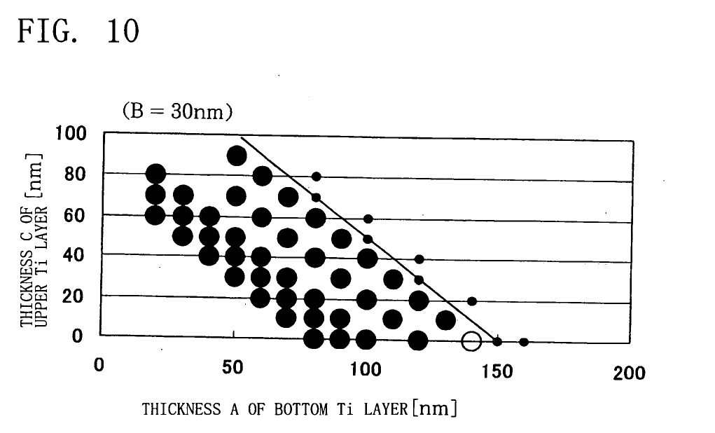

Plotted in FIG. 9 are the evaluation results of the insertion loss when the Al alloy layer 3 has a thickness B of 20 nm. As illustrated, when the sum (A+C) of the thickness A of the bottom Ti layer 2 and the thickness C of the upper Ti layer 4 is less than 150 nm, the maximum value of insertion loss has a difference less than 0.1 dB with the maximum value of the conventional surface acoustic wave devices.

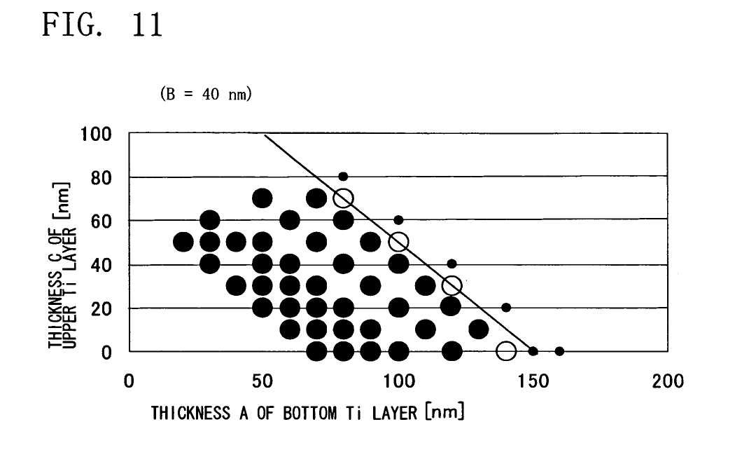

Plotted in FIG. 10 are the evaluation results of the insertion loss when the Al alloy layer 3 has a thickness B of 30 nm. As illustrated, when the sum (A+C) of the thickness A of the bottom Ti layer 2 and the thickness C of the upper Ti layer 4 is less than 150 nm, the maximum value of insertion loss has a difference less than 0.1 dB with the maximum value of the conventional surface acoustic wave devices.

Furthermore, plotted in FIG. 11 are the evaluation results of the insertion loss when the Al alloy layer 3 has a thickness B of 40 nm. As illustrated, when the sum (A+C) of the thickness A of the bottom Ti layer 2 and the thickness C of the upper Ti layer 4 is less than 150 nm, the maximum value of insertion loss has a difference less than 0.1 dB with the maximum value of the conventional surface acoustic wave devices.

As described above, when the sum (A+C) of the thickness A of the bottom Ti layer 2 and the thickness C of the upper Ti layer 4 is less than 150 nm, the maximum value of insertion loss has a difference less than 0.1 dB with the maximum value of the conventional surface acoustic wave devices, despite the thickness of the Al Alloy layer 3 insofar as the thickness B of the Al alloy layer 3 is in the range of 5 to 40 nm. Thus the thickness A of the bottom Ti layer 2 and the thickness C of the upper Ti layer 4 preferably have the following relationship:
A+C<150 nm (Expression 3)

Table 1 below shows the results of checking whether the short circuit occurs, in the case where the thickness A of the bottom Ti layer 2 and the thickness B of the Al alloy layer 3 are variously altered when the sum (A+C) of the thickness A of the bottom Ti layer 2 and the thickness C of the upper Ti layer 4 is 110 nm. The numerals in the table indicate the results obtained by the following counting procedure: a filter characteristics test was performed on 800 surface acoustic wave devices, and then an SEM observation was conducted on the devices that exhibit abnormal characteristics to count the number of defectives having the short circuit between the electrodes or between the electrode and the pad.

TABLE 1
A + C = 110 nm

| | Thick.B | | | | |
|---|---|---|---|---|---|
| Thick.A | 5 | 10 | 20 | 30 | 40 |
| 70 | 2 | 1 | 2 | 1 | 1 |
| 80 | 2 | 2 | 1 | 1 | 1 |
| 90 | 3 | 3 | 1 | 1 | 2 |
| 100 | 1 | 3 | 3 | 2 | 2 |
| 110 | 7 | 7 | 6 | 7 | 5 |

With reference to Table 1, when the thickness A of the bottom Ti layer 2 exceeds 100 nm, the number of the defectives is markedly increased, insofar as the thickness B of the Al alloy layer 3 is in the range of 5 to 40 nm.

Table 2 below shows, as in the same manner, the results of checking whether the short circuit occurs, in the case where the thickness A of the bottom Ti layer 2 and the thickness B of the Al alloy layer 3 are variously altered when the sum (A+C) of the thickness A of the bottom Ti layer 2 and the thickness C of the upper Ti layer 4 is 120 nm.

TABLE 2
A + C = 120 nm

| | Thick.B | | | | |
|---|---|---|---|---|---|
| Thick.A | 5 | 10 | 20 | 30 | 40 |
| 80 | 2 | 1 | 1 | 2 | 1 |
| 90 | 2 | 2 | 2 | 3 | 1 |
| 100 | 2 | 3 | 2 | 2 | 1 |
| 110 | 8 | 9 | 8 | 7 | 6 |
| 120 | 10 | 8 | 8 | 8 | 7 |

With reference to Table 2, when the thickness A of the bottom Ti layer 2 exceeds 100 nm, the number of the defectives is markedly increased, insofar as the thickness B of the Al alloy layer 3 is in the range of 5 to 40 nm.

Table 3 below shows, as in the same manner, the results of checking whether the short circuit occurs, in the case where the thickness A of the bottom Ti layer 2 and the thickness B of the Al alloy layer 3 are variously altered when the sum (A+C) of the thickness A of the bottom Ti layer 2 and the thickness C of the upper Ti layer 4 is 130 nm.

TABLE 3
A + C = 130 nm

| | Thick.B | | | | |
|---|---|---|---|---|---|
| Thick.A | 5 | 10 | 20 | 30 | 40 |
| 80 | 2 | 1 | 2 | 1 | 1 |
| 90 | 2 | 2 | 1 | 1 | 1 |
| 100 | 3 | 3 | 1 | 1 | 2 |
| 110 | 9 | 7 | 9 | 6 | 6 |
| 120 | 10 | 9 | 9 | 8 | 7 |

With reference to Table 3, when the thickness A of the bottom Ti layer 2 exceeds 100 nm, the number of the defectives is markedly increased, insofar as the thickness B of the Al alloy layer 3 is in the range of 5 to 40 nm.

Table 4 below shows, as in the same manner, the results of checking whether the short circuit occurs, in the case where the thickness A of the bottom Ti layer 2 and the thickness B of the Al alloy layer 3 are variously altered when the sum (A+C) of the thickness A of the bottom Ti layer 2 and the thickness C of the upper Ti layer 4 is 140 nm.

TABLE 4
A + C = 140 nm

| | Thick.B | | | | |
|---|---|---|---|---|---|
| Thick.A | 5 | 10 | 20 | 30 | 40 |
| 80 | 2 | 1 | 1 | 1 | 1 |
| 90 | 3 | 3 | 2 | 1 | 1 |
| 100 | 4 | 2 | 1 | 2 | 2 |
| 110 | 8 | 9 | 9 | 6 | 6 |
| 120 | 8 | 8 | 8 | 6 | 7 |

With reference to Table 4, when the thickness A of the bottom Ti layer 2 exceeds 100 nm, the number of the defectives is markedly increased, insofar as the thickness B of the Al alloy layer 3 is in the range of 5 to 40 nm.

As stated above, when the thickness A of the bottom Ti layer 2 exceeds 100 nm, the number of the defectives is markedly increased, despite the sum (A+C) of the thickness A of the bottom Ti layer 2 and the thickness C of the upper Ti layer 4, and the thickness B of the Al alloy layer 3 insofar as the sum (A+C) of the thickness A of the bottom Ti layer 2 and the thickness C of the upper Ti layer 4 is in the range of 110 to 140 nm, and the thickness B of the Al alloy layer 3 is in the range of 5 to 40 nm. Thus the thickness A of the bottom Ti layer 2 preferably has the following relationship:
A≦100 nm (Expression 4)

According to the above, when the thickness A of the bottom Ti layer 2 exceeds 100 nm, the number of the defectives having the short circuit is markedly increased. This is because a residue is likely to be left partially on a side surface of the bottom Ti layer 2 and on the piezoelectric substrate 1 to be exposed by etching when the thickness A of the bottom Ti layer 2 exceeds 100 nm.

With the surface acoustic wave device seen in FIG. 1, the bottom Ti layer 2, the Al alloy layer 3, and the upper Ti layer 4 are formed so that the thicknesses A, B, C of the layers 2, 3, 4 have the relationship in accordance with the abovementioned Expressions 1, 2 and 3, whereby the stress migration and electro migration are inhibited to obtain a higher durability than conventionally, processing accuracy in etching is held high, and the insertion loss, further, can be diminished.

Subsequently, described below are two embodiments of the surface acoustic wave devices to provide the surface acoustic wave filter according to the present invention.

### First Embodiment

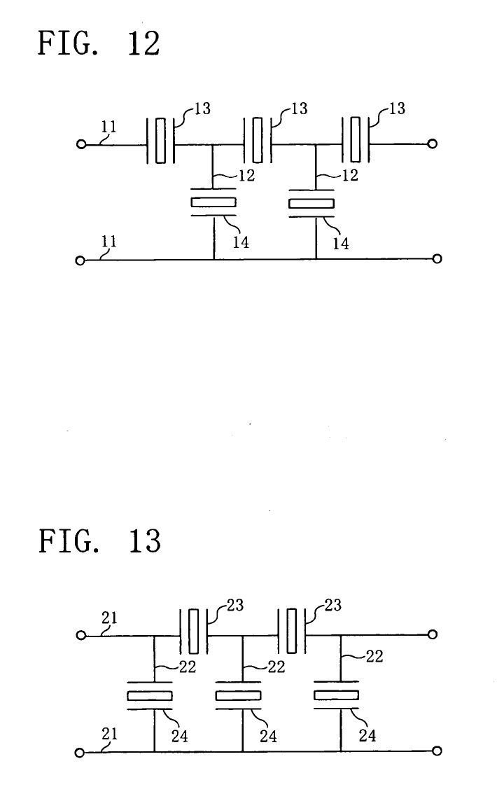

The surface acoustic wave filter of the present embodiment is provided on a transmitting circuit of communications equipments using radio waves of 800-MHz-band, and comprises three serial resonators 13, 13, 13 provided on one serial line 11 of two serial lines 11, 11 of a ladder-type circuit and two parallel resonators 14, 14 provided on two parallel lines 12, 12 for connecting to each other the two serial lines 11, 11 as seen in FIG. 12.

The serial resonator 13 and the parallel resonator 14 each comprises a surface acoustic wave device including an electrode 8 formed on a piezoelectric substrate 1 and to serve as an interdigital transducer, as seen in FIG. 1. The electrode 8 comprises, as superposed in the order starting from the piezoelectric substrate 1, a bottom Ti layer 2 of 90 nm in thickness, Al alloy layer 3 of 30 nm in thickness and made of AlVCu, upper Ti layer 4 of 30 nm in thickness, and an Al alloy layer 7 of 230 nm in thickness and made of AlVCu.

The surface acoustic wave device of the present invention is fabricated by the following process. Successively formed, by a DC sputterer, on a wafer of lithium tantalite substrate of 350 μm in thickness and cut into 36-degree Y-shape are a Ti film having a thickness of 90 nm, an AlVCu film made of AlVCu alloy containing Cu of 1 wt. % to overall weight and V of 0.15% and having a thickness of 30 nm, a Ti film having a thickness of 30 nm, and an AlVCu film made of the same AlVCu alloy and having a thickness of 230 nm. When forming each film, power of 1 kW is applied to the electrode (sputtering target) in an argon gas atmosphere of 0.32 Pa.

Subsequently a resist pattern having a desired shape is formed on the wafer on which the films have been formed, and an interdigital transducer, a pair of reflectors, and input and output pads are thereafter formed by reactive ion etching (RIE) with use of mixture of BCl₃ gas and Cl₂ gas. In this case, the period of electrode finger (=wavelength λ of the surface acoustic wave) of the serial resonator 13 is set to 4.50 to 4.70 μm, the period of electrode finger of the parallel resonator 14 is set to 4.70 to 4.90 μm, an aperture width of each resonator is set to 50 to 250 μm, and the number of pair of the electrode fingers is set 25 to 200. By altering the aperture width of each resonator and the number of pair of the electrode fingers, the capacitances of the resonator and the area of the resonators on a chip are adjusted.

Lastly, the wafer is cut every film pattern, to thereby obtain the surface acoustic wave devices of the present embodiment.

### Second Embodiment

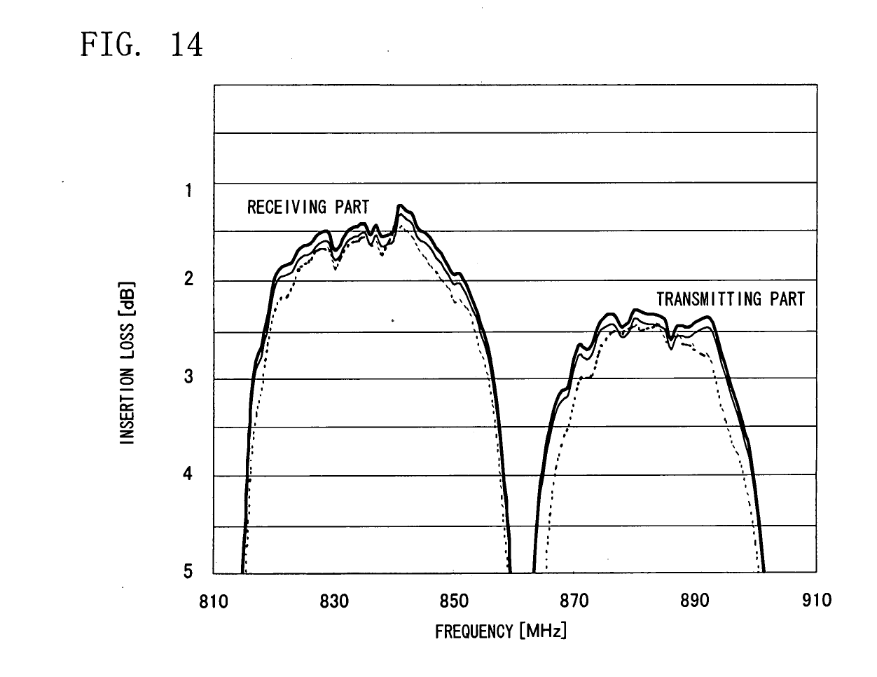

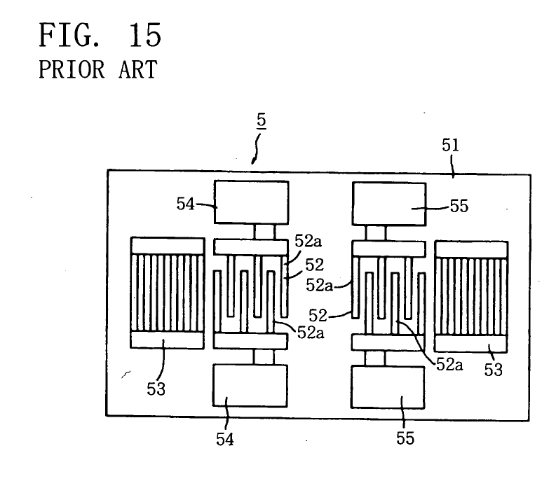

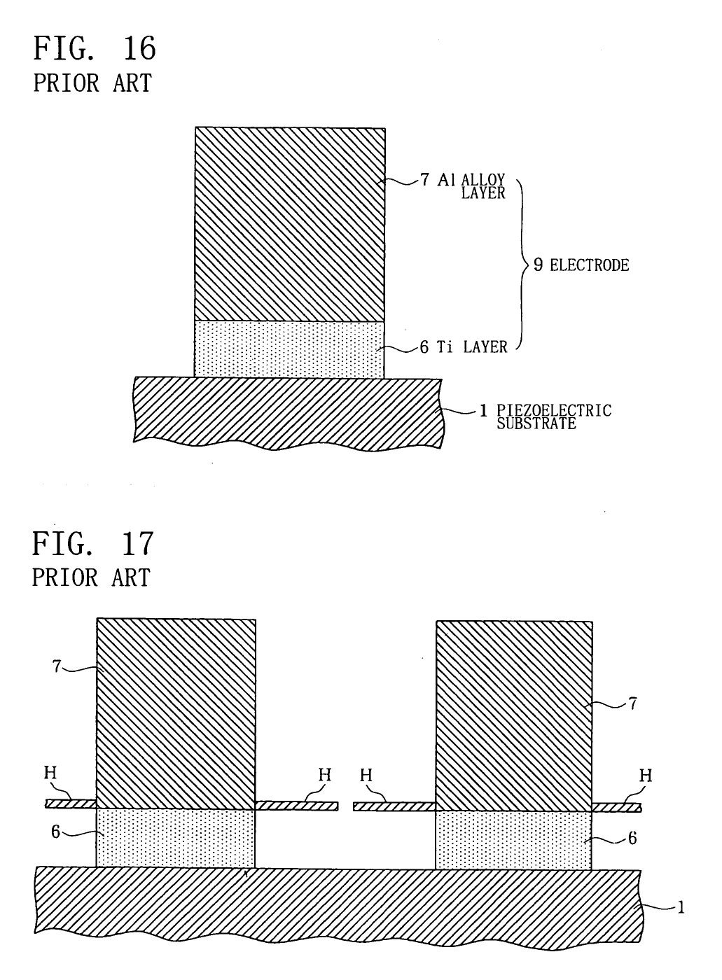

The surface acoustic wave filter of the present embodiment is provided on a receiving circuit of communications equipments using radio waves of 800-MHz-band, and comprises two serial resonators 23, 23 provided on one serial line 21 of two serial lines 21, 21 of a ladder-type circuit and three parallel resonators 24, 24, 24 provided on three parallel lines 22, 22, 22 for connecting to each other the two serial lines 21, 21, as seen in FIG. 13.

The serial resonator 23 and the parallel resonator 24 each comprises a surface acoustic wave device including an electrode 8 formed on a piezoelectric substrate 1 and to serve as an interdigital transducer, as seen in FIG. 1. The electrode 8 comprises, as superposed in the order starting from the piezoelectric substrate 1, a bottom Ti layer 2 of 90 nm in thickness, Al alloy layer 3 of 30 nm in thickness and made of AlVCu, upper Ti layer 4 of 30 nm in thickness, and an Al alloy layer 7 of 230 nm in thickness and made of AlVCu.

The fabricating process is the same as that of the first embodiment, and therefore will not be described specifically, but in the patterning process, the period of electrode finger of the serial resonator 23 is set to 4.10 to 4.50 μm, the period of electrode finger of the parallel resonator 24 is set to 4.40 to 4.65 μm, an aperture width of each resonator is set to 20 to 250 μm, and the number of pair of the electrode fingers is set 25 to 250.

The surface acoustic wave filters of the first embodiment and the second embodiment can exhibit a higher durability than conventionally, and more satisfactory filter characteristics diminished in insertion loss than conventionally.

In the first embodiment and the second embodiment, the thicknesses A, B, C of the bottom Ti layer 2, the Al alloy layer 3, and the upper Ti layer 4 are respectively set to the above values. The values are, however, not limited to the above, and can be set to given values insofar as the thicknesses A, B, C of the layers 2, 3, 4 have the relationship in accordance with the abovementioned Expressions 1, 2 and 3.

The present inventors fabricated various surface acoustic wave filters to substantiate the advantage of the present invention, and evaluated the frequency characteristics of the insertion loss in the pass band.

Fabrication of Surface Acoustic Wave Filters of the First Embodiment and the Second Embodiment

We fabricated transmitting surface acoustic wave filters in the First Embodiment and receiving surface acoustic wave filters in the Second Embodiment, according to the fabrication process described. The number of pair of electrodes of each of reflectors, the number of fingers and aperture width of the resonator, and the period of electrode finger were respectively set to the values shown in Table 5 below.

TABLE 5

| | | Number of | Number of | Aperture | Period of |
|---|---|---|---|---|---|
| | Resonator | pair of | fingers of | width | electrode |
| | Connect. | electrodes | reflector | (μm) | finger (μm) |
| Embodi. 1 | serial | 175 | 50 | 80 | 4.562 |
| | parallel | 125 | 72 | 170 | 4.780 |
| | serial | 143 | 50 | 55 | 4.565 |
| | parallel | 125 | 72 | 170 | 4.780 |
| | serial | 199 | 50 | 100 | 4.565 |
| Embodi. 2 | parallel | 173 | 70 | 70 | 4.452 |
| | serial | 239 | 70 | 32 | 4.241 |
| | parallel | 201 | 70 | 250 | 4.462 |
| | serial | 239 | 70 | 32 | 4.241 |
| | parallel | 173 | 70 | 70 | 4.452 |

Fabrication of Surface Acoustic Wave Filters of the Comparative Embodiments 1 and 2

The transmitting surface acoustic wave filters having four-layer structure electrodes of each resonator (Comparative Embodiment 1) and the receiving surface acoustic wave filters (Comparative Embodiment 2) were fabricated in the same manner as that of the first embodiment and the second embodiment except that a Ti film of 120 nm in thickness, an AlVCu film of 30 nm in thickness, a Ti film of 40 nm in thickness, and an AlVCu film of 178 nm in thickness were successively formed on the wafer.

Fabrication of Surface Acoustic Wave Filters of the Conventional Embodiments 1 and 2

The transmitting surface acoustic wave filters (Conventional Embodiment 1) and the receiving surface acoustic wave filters (Conventional Embodiment 2) were fabricated in the same manner as that of the first embodiment and the second embodiment except that an AlVCu film of 416 nm in thickness were only formed on the wafer to provide a single-layer structure electrode.

Evaluation Results

FIG. 14 shows the frequency characteristics of the insertion loss in the pass band of the above various surface acoustic wave filters. In the graph, a bold line indicates the frequency characteristics of the surface acoustic wave filters of the first embodiment and the second embodiment, a broken line indicates the frequency characteristics of the surface acoustic wave filters of the comparative example 1 and the comparative example 2, and a thin line indicates the frequency characteristics of the surface acoustic wave filters of the conventional examples 1 and 2.

The insertion loss of the surface acoustic wave filters of the first example, wherein the thickness A of the bottom Ti layer 2 and the thickness C of the upper Ti layer 4 have the relationship in accordance with the abovementioned Expression 3, is smaller in the frequency band of 824 to 849 MHz than that of the filters of the conventional example 1 having single-layer structure electrodes of each resonator, as illustrated. Furthermore, the surface acoustic wave filters of the second example are more diminished in insertion loss in the frequency band of 869 to 894 MHz than the filters of the conventional example 2.

On the other hand, the surface acoustic wave filters of the comparative examples 1 and 2, wherein the thickness A of the bottom Ti layer 2 and the thickness C of the upper Ti layer 4 have no relationship in accordance with the abovementioned Expression 3, is more increased in insertion loss than the filters of the conventional examples 1 and 2.

According to the results described, the thicknesses of A and C of the bottom Ti layer 2 and the upper Ti layer 4 each constituting the electrodes of each resonator have the abovementioned relationship in accordance with Expression 3, to thereby provide the surface acoustic wave filter exhibiting more satisfactory filter characteristics than conventionally.

1. A surface acoustic wave device comprising an electrode to serve as an interdigital transducer and formed on a piezoelectric substrate, the electrode including a first layer made of Ti, a second layer made of Al or Al alloy, a third layer made of Ti, and a fourth layer made of Al or Al alloy, which are superposed one after another on a surface of the piezoelectric substrate, a thickness A of the first layer being greater than a thickness C of the third layer and being not less than 50 nm nor more than 120 nm, the sum of the thickness A of the first layer and the thickness C of the third layer being less than 150 nm.

2. A surface acoustic wave device according to claim 1, wherein a thickness B of the second layer is not less than 10 nm nor more than 30 nm.

3. A surface acoustic wave device according to claim 1, wherein the thickness A of the first layer is not greater than 100 nm.

4. A surface acoustic wave device according to claim 2, wherein the thickness A of the first layer is not greater than 100 nm.

5. A surface acoustic wave filter comprising at least one surface acoustic wave device, the surface acoustic wave device comprising an electrode to serve as an interdigital transducer and formed on a piezoelectric substrate, the electrode including a first layer made of Ti, a second layer made of Al or Al alloy, a third layer made of Ti, and a fourth layer made of Al or Al alloy, which are superposed one after another on a surface of the piezoelectric substrate, a thickness A of the first layer being greater than a thickness C of the third layer and being not less than 50 nm nor more than 120 nm, the sum of the thickness A of the first layer and the thickness C of the third layer being less than 150 nm.

6. A surface acoustic wave device according to claim 5, wherein a thickness B of the second layer is not less than 10 nm nor more than 30 nm.

7. A surface acoustic wave device according to claim 5, wherein the thickness A of the first layer is not greater than 100 nm.

8. A surface acoustic wave device according to claim 6, wherein the thickness A of the first layer is not greater than 100 nm.
